(19) United States
(12) Patent Application Publication
(10) Pub. No.: US 2011/0244661 A1
(43) Pub. Date: Oct. 6, 2011

(54) Large Scale High Quality Graphene Nanoribbons From Unzipped Carbon Nanotubes

(75) Inventors: Hongjie Dai, Cupertino, CA (US); Liying Jiao, Stanford, CA (US)

(73) Assignee: The Board of Trustees of the Leland Stanford Junior University, Palo Alto, CA (US)

(21) Appl. No.: 12/763,888

(22) Filed: Apr. 20, 2010

Related U.S. Application Data
(60) Provisional application No. 61/320,737, filed on Apr. 4, 2010.

(51) Int. Cl. H01L 21/20; C01B 31/04; B05D 5/12

(52) U.S. Cl. 438/478; 423/448; 427/58; 977/700; 977/762; 977/752; 977/932; 257/E21.09

(57) ABSTRACT

A new method is disclosed for large-scale production of pristine few-layer graphene nanoribbons (GNRs) through unzipping of mildly gas-phase oxidized, and, optionally, metal-assisted oxidized, multiwalled and few-walled carbon nanotubes. The method further comprises sonication in an organic solvent. High-resolution transmission electron microscopy revealed nearly atomically smooth edges for narrow GNRs (2-30 nm). The GNRs exhibit ultra-high quality with low ratios of disorder (D) to graphitic (G) Raman bands (I_{D}/I_{G}). Further electrical transport through the valence-band of the GNRs exhibits metallic behavior with little disorder effect. At low temperatures, the GNRs exhibit high conductance and phase coherent electron transport through entire lengths. Sub 10 nm GNRs exhibit high on/off electrical switching useful for field effect transistors may also be prepared according to the present methods. The high yield synthesis of pristine GNRs enables facile fabrication of GNR devices, making these materials easily accessible for a wide range of fundamental and practical applications.

### CROSS-REFERENCE TO RELATED APPLICATIONS

This application claims priority from U.S. Provisional Patent Application No. 61/320,737 filed on Apr. 4, 2010, which is hereby incorporated by reference in its entirety.

### STATEMENT OF GOVERNMENTAL SUPPORT

This invention was made with Government support under contract N00014-08-1-0860 awarded by the Office of Naval Research and under contract HR0011-07-03-0002 awarded by DARPA. The U.S. Government has certain rights in this invention.

### REFERENCE TO SEQUENCE LISTING, COMPUTER PROGRAM, OR COMPACT DISK

None

### BACKGROUND OF THE INVENTION

1. Field of the Invention

The present invention relates to the field of materials and particularly to the field of graphene nanoribbons.

2. Related Art

Presented below is background information on certain aspects of the present invention as they may relate to technical features referred to in the detailed description, but not necessarily described in detail. The discussion below should not be construed as an admission as to the relevance of the information to the claimed invention or the prior art effect of the material described.

Graphene nanoribbon (GNR) has emerged as an interesting material with a wealth of electronic and spin transport properties (Li et al 2008, Science 319: 1229; Wang et al 2008, Phys. Rev. Lett. 100: 206803; Wang et al 2009, Science 324: 768; Chen et al 2007, Physica. E 40: 228; Han et al 2007, Phys. Rev. Lett. 98: 206805). GNRs, if made into quasi-one dimensional structures with narrow widths (<˜10 nm) and atomically smooth edges, are predicted to exhibit band gaps useful for room-temperature transistor operations with excellent switching speed and high carrier mobility (potentially even ballistic transport). Theoretical work predicted that quantum confinement and edge effects make narrow GNRs (width <˜10 nm) into semiconductors, which differs from single-walled carbon nanotubes that contain ˜⅓ metallic species. Currently, large scale production of high quality, nearly pristine GNRs remains a challenge. Lithographic (Chen et al 2007, Physica. E 40: 228; Han et al 2007, Phys. Rev. Lett. 98: 206805; Tapaszto et al 2008 Nat. Nanotechnol. 3: 397; Bai et al 2009, Nano Lett. 9: 2083), chemical (Datta et al 2008, Nano Lett. 8: 1912; Ci et al 2008, Nano Res. 1: 116; Campos et al 2009, Nano Lett. 9: 2600; Campos-Delgado et al 2008, Nano Lett. 8: 2773; Wei et al 2009, J. Am. Chem. Soc. 131: 11147) and sonochemical (Li et al 2008, Science 319: 1229) methods have been developed to make GNRs. Recently, GNR formations by unzipping carbon nanotubes (CNTs) were reported (as described below). Two groups successfully unzipped multi-walled carbon nanotubes (MWCNTs) in solution-phase by using potassium permanganate oxidation (Kosynkin et al 2009 Nature 458: 872) and lithium and ammonia reactions (Cano-Marquez et al 2009, Nano Lett. 9: 1527), respectively. Only wide, heavily oxidized and defective GNRs were made due to extensive oxidation involved in the unzipping process. Jiao et al (Nature 2009, 458: 877-880) developed an approach to high quality narrow GNRs by unzipping MWCNTs using a masked gas-phase plasma etching approach. However, the method was limited to GNR formation on substrates. More recently, unzipping methods such as catalytic cutting (Elias et al 2009, Nano Lett. ASAP DOI: 10.1021/n1901631z) and high current pulse burning (Kim et al 2009, Appl. Phys. Lett. 95: 083103) have been reported, but the quality and yield of GNRs were unknown. Thus far, a method capable of producing large amounts of high quality GNRs is still lacking.

### Specific Patents and Publications

Jiao et al., “Narrow graphene nanoribbons from carbon nanotubes,” Nature 458: 877-880 (2009) describes the unzipping of highly crystalline multiwalled carbon nanotubes by partially embedding tubes in a polymer film and then etching them with argon plasma. The film was then removed using solvent vapor and the resulting nanoribbons were heated at 300° C. to remove any residual polymer.

Kosynkin et al., “Longitudinal unzipping of carbon nanotubes to form graphene nanoribbons,” Nature 458: 872-876 (2009) describes making graphene sheets and ribbons from multiwalled nanotubes by concentrated sulphuric acid treatment followed by potassium permanganate at room temperature and finally heating them at 55-70° C. This technique works well with nanotubes that have many structural defects on their surfaces (such as those made by chemical vapor deposition). But it is less effective with more crystalline nanotubes produced by other methods such as laser ablation or arc discharge.

Zhang et al., “Transforming carbon nanotube devices into carbon nanoribbon devices,” J. Am. Chem. Soc. 131: 13460-13463 (2009) discloses an extension of the nanotube longitudinal unzipping process to convert electrode-bound multiwalled carbon nanotube (MWCNT) devices into graphene nanoribbon devices.

Cano-Marquez et al., “Graphene sheets and ribbons produced by lithium intercalation and exfoliation of carbon nanotubes,” Nano Lett. 9: 1527-1533 (2009) describes a method for unzipping multiwalled carbon nanotubes in which alkali-metal atoms intercalate between the concentric cylinders of the nanotubes. The atoms are then washed out, which causes the tubes to open along their axes.

Kim et al., “Fabrication of graphene layers from multiwalled carbon nanotubes using high DC pulse,” Appl. Phys. Lett. 95: 083103 (2009) discloses the fabrication of graphene layers from multiwalled carbon nanotubes (MWCNTs) with a high direct current pulse through a pulsed current sintering process.

Elias et al., “Longitudinal cutting of pure and doped carbon nanotubes to form graphitic nanoribbons using metal clusters as nanoscalpels,” Nano Lett. ASAP DOI 10.1021/n1901631z (2009) describes the use of transition metal nanoparticles (Ni or Co) to longitudinally cut open multiwalled carbon nanotubes to create graphitic nanoribbons.

Li et al. “Chemically Derived, Ultrasmooth Graphene Nanoribbon Semiconductors,” Science, 319:1229-1232 (2008) describes the production of nanoribbons using exfoliated graphite dispersed into 1,2-dichloroethane (DCE) solution. This method does not disclose the use of intercalation, and the use for solubilization of PmPV (poly(m-phenylenevinylene-co-2,5-dioctyloxy-p-phenylenevinylene) dispersant. Described there, by authors including the present inventors, is a chemical route to produce graphene nanoribbons (GNR) with width below 10 nanometers, as well as single ribbons with varying widths along their lengths or containing lattice-defined graphene junctions for potential molecular electronics. The GNRs were solution-phase derived, stably suspended in solvents with non-covalent polymer functionalization, and exhibited ultra-smooth edges with possibly well-defined zigzag or armchair edge structures. Electrical transport experiments showed that unlike single-walled carbon nanotubes, all of the sub-10 nanometer GNRs produced were semiconductors and afforded graphene field effect transistors (FET) with on-off ratios ˜10⁷ at room temperature. The graphene nanoribbons (GNR) discussed below in connection with the present invention have narrow widths (10-30 nm) and atomically smooth edges, which are predicted to exhibit band gaps useful for room temperature transistor operations with excellent switching speed and high carrier mobility (potentially even ballistic transport). In addition the GNRs discussed below in the present invention exhibit ultra-high quality with low ratios of disorder (D) to graphitic (G) Raman bands (I_{D}/I_{G}) and the highest conductivity reported to date.

As will be described below, GNRs according to the present invention are made by processes distinguishable from those cited above, at least in part because GNRs of the present method are made in high yields by a simple two step process involving, e.g., of gaseous phase oxidation followed by a mechanical step such as sonication in an organic solvent. Separation, e.g., by ultracentrifugation yields GNRs in the supernatant.

### BRIEF SUMMARY OF THE INVENTION

The following brief summary is not intended to include all features and aspects of the present invention, nor does it imply that the invention must include all features and aspects discussed in this summary.

The present invention comprises, in certain aspects, a method for production of graphene nanoribbons, comprising steps of: heating closed carbon nanostructures at a temperature, between about 400° C. and 700° C., sufficient to induce oxidation but not thermal decomposition of the closed carbon nanostructures and produce partially etched closed carbon nanostructures; (b) dispersing said partially etched closed carbon nanostructures in an organic solvent; (c) mechanically agitating said partially etched closed carbon nanostructures in said organic solvent under conditions whereby said partially etched closed carbon nanostructures open to form graphene nanoribbons; and (d) recovering said graphene nanoribbons from said organic solvent.

The method may also include the use of a metal to aid in oxidation. The method may also include a step wherein said recovering comprises centrifugation, and said graphene ribbons are in a supernatant.

In certain aspects, the method of the invention may include a method wherein said graphene nanoribbons comprise more than 60% of solid carbon compounds in said supernatant.

In certain aspects, the method of the invention may include a method wherein said heating takes place between 450° C. and 700° C. In certain aspects, the method of the invention may include a method wherein said organic solvent is 1,2-dichloroethane. In certain aspects, the method of the invention may include a method wherein the method further comprises the step of adding to said partially etched carbon nanostructures in an organic solvent a polymer for contacting and separating the nanostructures. Said polymer may be poly (m-phenylenevinylene-co-2,5-dioctoxy-p-phenylenevinylene).

In certain aspects, the method of the invention may include a method wherein said graphene nanoribbons have a width between about 2 nm and 30 nm. In certain aspects, the method of the invention may include a method wherein said graphene nanoribbons have atomically smooth edges. In certain aspects, the method of the invention may include a method wherein the multiwalled carbon nanostructures are multiwalled carbon nanotubes. In certain aspects, the method of the invention may include a method wherein single-, bi- and tri layer graphene nanoribbons together comprise more than 50% of said graphene nanoribbons. In certain aspects, the method of the invention may include a method further comprising the step of applying recovered graphene nanoribbons to electrodes to form a GNR device. In certain aspects, the method of the invention may include a method wherein the electrodes are part of an FET device. In certain aspects, the method of the invention may include a method and device wherein said GNR device has an electrical conductance of up to 5 e2/h. In certain aspects, the method of the invention may include a method wherein the resistivity of said GNR device is less than 2 kΩ. In certain aspects, the method of the invention may include a method wherein the resistivity of said GNR device is less than 1.8 kΩ. In certain aspects, the method of the invention may include a method wherein said GNR device exhibits phase coherent transport at low temperature.

In certain aspects, the invention may include a graphene nanoribbon having a discrete number of layers, between one and four, a width between about 10 and 30 nm and having surface integrity sufficient to yield a Raman Peak ratio of I_{D}/I_{G} less than about 0.5. In certain aspects, the invention may include a device comprising a graphene nanoribbon having a discrete number of layers, between one and four, a width less than about 10 nm, and an on/off ratio (ratio of on current to off current) of at least about 10⁶, for use in a field effect transistor.

In certain aspects, the present invention comprises oxidation of a closed carbon nanostructure (CCN) using a metal, which method produces narrower GNRs. The method using a metal may comprise performing the above-described calcination (heating)/sonication method with an additional mixing with a metal and heating step. The method may comprise the step of heating said partially etched closed carbon nanostructures in the presence of a metal. The metal may be copper, although other metals are known to work in assisting controlled oxidative etching in the CCN. This method produces narrower GNRs, and it is thought that the metal-assisted oxidation introduces further defects for unzipping the CCN. The produced graphene nanoribbons may be less than about 10 nm wide.

### BRIEF DESCRIPTION OF THE DRAWINGS

FIG. 1A is a schematic diagram that shows unzipping of multi-walled carbon nanotubes (MWCNTs) by the present process. According to the exemplified process, in a mild gas-phase oxidation step, oxygen was reacted with pre-existed defects on MWCNTs to form etch pits on the sidewalls. In the solution-phase sonication step, sonochemistry and hot gas bubbles enlarged the pits and unzipped the tubes to form graphene nanoribbons (GNR). FIG. 1B is a schematic representation of one layer of the bi-layer GNR.

FIGS. 2A-C are atomic force microscopy (AFM) images of pristine, partially and fully unzipped MWCNTs, respectively. The heights of GNRs shown in (FIG. 2B) and (FIG. 2C) are 1.4 and 1.6 nm, respectively, much lower than the pristine MWCNT shown in (FIG. 2A) (height ˜9 nm).

FIG. 3 shows AFM images of unzipped products after ultracentrifuging at different speed and time. FIG. 3A, 20,000 rpm for 1 hr. FIG. 3B, 30,000 rpm for 1 hr. FIG. 3C, 40,000 rpm for 1 hr. FIG. 3D, 40,000 rpm for 2 hrs.

FIGS. 4A and 4B show height and width distribution respectively of GNRs made by the present method.

FIG. 5 is a set of microscopy images of GNRs. (FIG. 5A) An AFM image of unzipped MWCNTs deposited on SiO₂/Si substrate, showing a high percentage of bi- and tri-layer GNRs (˜60%). (FIG. 5B) A zoom-in AFM image of a part in (FIG. 5A), showing smooth edges of GNRs. The heights and widths of the three GNRs from top to bottom were: 1.8 nm, 18 nm; 1.4 nm, 48 nm; 1.4 nm, 22 nm, respectively. (FIG. 5C) A transmission electron microscopy (TEM) (acceleration voltage=200 kV) image of a ˜12-nm-wide GNR with a kink due to folding. The dark spots on the substrate are nanocrystalline domains within the porous silicon grids (20). (FIG. 5D) TEM image of the kink on the GNR shown in (FIG. 5C). (FIG. 5E) and (FIG. 5F) TEM (acceleration voltage=120 kV) images of GNRs suspended over the holes of porous silicon grids, showing nearly atomically smooth edges. The widths of the GNRs shown in (FIG. 5E) and (FIG. 5F) were ˜12 and 10 nm, respectively. The amorphous coating on the GNR shown in (FIG. 5E) was PmPV used to suspend GNRs.

FIG. 6 shows Raman spectra of the pristine and oxidized MWCNTs, and the unzipped products.

FIG. 7 shows Raman spectroscopy of individual GNRs. (FIG. 7A) and (FIG. 7B), Raman spectrum of a bi- and tri-layer GNR (W ˜20 nm) on SiO₂/Si substrates, respectively. Inset of FIGS. 7A and 7B show, AFM images and G-band images of the same GNRs on the same length scale. The I_{D}/I_{G} ratios of these two GNRs are 0.3 and 0.5, respectively. (FIG. 7C) Comparison of I_{D}/I_{G} of bi-layer GNRs with 10-30 nm widths made by different methods, including present method, and by lithographic patterning and plasma unzipping.

FIG. 8 is a typical Raman spectrum of a 20-nm-wide bilayer GNR made by lithographic patterning, showing an I_{D}/I_{G} of ˜1.3, much higher than that of GNRs made by the current unzipping method. Inset is an AFM image of the GNR.

FIG. 9 is a schematic diagram illustrating a simple GNR FET device.

FIG. 10A shows I_{ds}-V_{gs} curve of a 12-nm-wide bilayer GNR after electrical annealing. FIG. 10B shows I_{ds}-V_{gs} curve of a 20-nm-wide trilayer GNR after electrical annealing. V_{ds}=100 mV, pressure: ˜10-6 Torr.

FIG. 11 shows I_{ds}-V_{gs} curves of two bilayer GNRs made by lithographic patterning, V_{ds}=1 mV. FIG. 11A, W ˜27 nm, L ˜310 nm. FIG. 11B, W ˜29 nm, L ˜480 nm.

FIG. 12 is a set of four AFM images of sub-10 nm GNRs obtained by metal-assisted oxidation during calcination. The widths of GNRs shown in FIGS. 12A-D show GNRs of 2 nm (FIG. 12A), 2 nm (FIG. 12B), 7 nm (FIG. 12C) and 8 nm (FIG. 12D).

FIG. 13 is a line graph that shows transfer characteristics (current vs. gate voltage I_{ds}-V_{gs}) under various V_{ds} for a 3-nm-wide GNR device. Iₒₙ/I_{off} ratio of more than 10⁶ is achieved at room temperature. I_{ds} drain source current, V_{gs} gate source voltage, V_{ds}, drain source voltage.

### DETAILED DESCRIPTION OF THE PREFERRED EMBODIMENT

### Definitions

Unless defined otherwise, all technical and scientific terms used herein have the same meaning as commonly understood by those of ordinary skill in the art to which this invention belongs. Although any methods and materials similar or equivalent to those described herein can be used in the practice or testing of the present invention, the preferred methods and materials are described. Generally, nomenclatures utilized in connection with, and techniques of, physics and chemistry are those well known and commonly used in the art. Certain experimental techniques, not specifically defined, are generally performed according to conventional methods well known in the art and as described in various general and more specific references that are cited and discussed throughout the present specification. For purposes of clarity, the following terms are defined below.

The term “about” is used in its ordinary sense and is based herein on approximations brought about by measurement error, or insignificant variations beyond the stated range. Where the meaning is not reasonably clear to one skilled in the art from the context, it may be considered to be a variation of not more than plus or minus 10% of a stated numerical value.

The term “graphene material” means a material which comprises at least one one-atom-thick planar sheet of sp²-bonded carbon atoms that are densely packed in a honeycomb crystal lattice, and, further, contains an intact ring structure of carbon atoms and aromatic bonds throughout at least a majority of the interior sheet and lacks significant oxidation modification of the carbon atoms. The graphene material may contain non-carbon atoms at its edges, such as OH and COOH functionalities. Preferably at least 90% of the interior aromatic bonds are intact. The present pristine graphene material is distinguishable from graphene oxide in that it has a lower degree of oxygen containing groups such as OH, COOH and epoxide. The present graphene material may include sheets and graphene ribbons, the two being distinguishable by size, with a ribbon typically having a relatively narrow width, which can be as low as about 10 nm. Graphene nanoribbons (GNR) are thin strips of graphene or unrolled single-walled carbon nanotubes. The graphene ribbons were originally introduced as a theoretical model by M. Fujita et al. to examine the edge and nanoscale size effect in graphene. Their electronic states largely depend on the edge structures (armchair or zigzag). The graphene ribbons have a width of not more than about 100 nm.

The graphene material may be characterized as comprising “few layers,” meaning between one and ten layers, preferably between one and three layers, typically between one and three layers (bi-layer and tri-layer).

The term “pristine graphene material” means a graphene material having no significant density of oxygen containing groups or other non-carbon atoms in the plane of the graphene, and very few broken bonds or missing atoms. The term “pristine” is used in its accepted meaning in the art (see, e.g., Carbon 45 (2007)1558-1565) in accordance with the foregoing description.

The term “atomically smooth edge” or “ultra-smooth edge,” as is known in the art, means that the edges of a layer of graphene material are not substantially chemically modified, and, more importantly, extend along a line of intact aromatic rings.

The term “calcination” (also referred to as “calcining”) is a thermal treatment process applied to ores and other solid materials in order to bring about a thermal decomposition, phase transition, removal of a volatile fraction or oxidation. The calcination process normally takes place at temperatures below the melting point of the product materials. Calcination is carried out in furnaces or reactors (sometimes referred to as kilns) of various designs. In the case of a carbon nanotube, calcination generally will be carried out in air heated to about 400 to 700° C. Calcination of the present closed carbon nanostructures preferably takes place in air, but may be carried out in a variety of gases containing oxygen, and at a variety of pressures, such as a few Torr, so long as a mild oxidation of the nanotube results.

The term “closed carbon nanostructure” means a carbon graphitic particle that is formed into a closed shape, i.e., a carbon nanotube tube, sphere (e.g., “Buckyball”), cone or the like having joined edges forming a continuous surface that can be opened up to form a planar graphene sheet, such as a graphene nanoribbon. Closed carbon nanostructures as defined here include a single walled carbon nanotube (SWNT), a multiwalled carbon nanotube (MWNT), the family of fullerenes C70, C76 [Dorset D. L., Fryer J. R., J. Phys. Chem. B 105 2356 (2001)], C84 [Kuzuo R. et al., Phys. Rev. B 49 5054 (1994)], C60 in a crystalline form, carbon nanocones [Ge M. And Sattler K., Chem. Phys. Lett. 220 192 (1994)], carbon nanohorns [Ijima S, Nature (London) 354 56 (1990], nanoscale carbon toroidal structures [Itoh S. et al., Phys. Rev B 47 1703 (1993)] and helicoidal tubes [Amelinckx S. et al., Science 265 635 (1994)].

### Overview

Described below are methods of making highly conducting graphene nanoribbons (GNR) and the like which are pristine, i.e., free of significant defects and chemical modifications within the plane of the structures, such as oxidation. The graphene nanoribbons exhibit ultra-high quality with atomically smooth edges for narrow GNRs (10-30 nm), low ratios of disorder (D) to graphitic (G) Raman bands (I_{D}/I_{G}) and high electrical conductivity. GNRs of a width ranging from 10-30 nm can be obtained by the present method and can be made down to 2 nm width by metal assisted oxidation during calcination. The obtained GNRs have atomically smooth edges and have I_{D}/I_{G} ratio of ˜0.2. The GNRs obtained by the present method show conductance of up to 5 e²/h. The resistivity of obtained GNRs may be less than 2 kΩ, preferably less than 1.8 kΩ.

Also described below is a method of making these GNR comprising the steps of: providing as a starting material a graphitic material, which may be a carbon nanotube; then subjecting this material to gaseous phase oxidation with and without metal assistance/catalysis; and sonicating in an organic solvent followed by ultracentrifugation, whereby one may recover graphene nanoribbons as separate molecules from the solution in a high yield. The yield may be more than 60% of GNRs in the supernatant after high-speed or ultracentrifugation. The GNRs have also been found to display phase coherent electron transport. The mild oxidation step introduces small defects that are opened during sonication.

Described below are methods involving gaseous phase oxidation and mechanical sonication in an organic solvent of multiwalled carbon nanotubes that can produce pristine few-layer graphene nanoribbons.

High-resolution transmission electron microscopy (HRTEM) reveals that the present process results in nearly atomically smooth edges for narrow GNRs (2-30 nm). The GNRs exhibit ultra-high quality with low ratios of disorder (D) to graphitic (G) Raman bands (_{ID}/_{IG}) and the highest electrical conductivity reported to date. Further electrical transport through the valence-band of the GNRs exhibits metallic behavior with little disorder effect. At low temperatures the GNRs exhibit high conductance of 3-4^{e2}/h and phase coherent electron transport through the entire lengths, evidenced by Fabry-Perot interference patterns in transport characteristics. The high-yield synthesis of pristine GNRs enables facile fabrication of GNR devices, making these materials easily accessible for a wide range of fundamental and practical applications.

In some cases, a graphene nanoribbon having a discrete number of layers, between one and four, a width less than about 10 nm, and an on/off ratio of the source/drain current of at least about 10⁶, for use in a field effect transistor operating at room temperature can be formed. This ratio is further described and explained in U.S. Pat. No. 5,854,139, “Organic field-effect transistor and production thereof,” issued Dec. 29, 1998, where it is stated that on-off ratios for FETs have been problematic in the past.

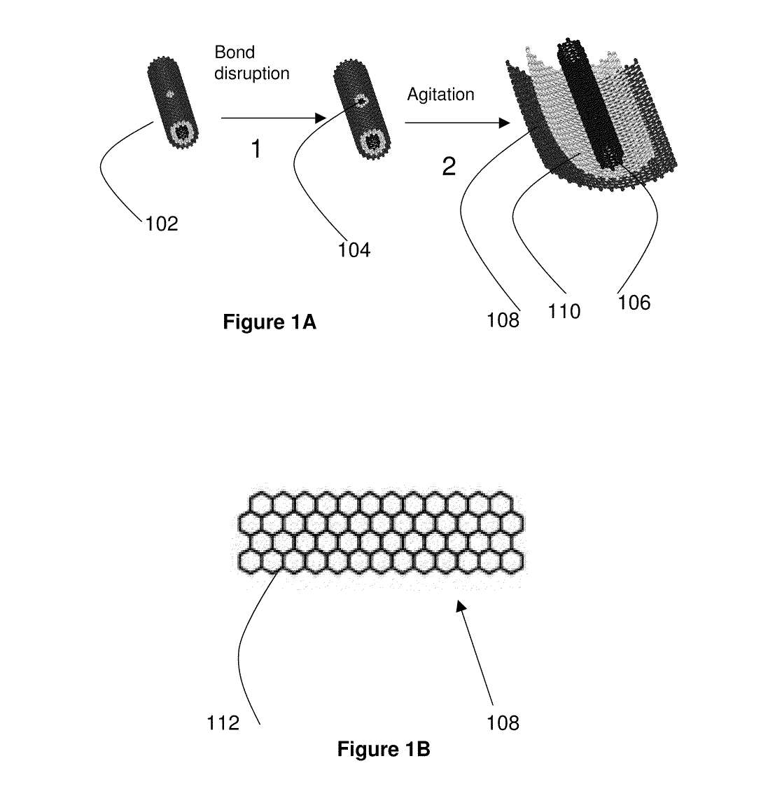

Also described below is a method in which the bond disruption step 1 (FIG. 1) includes both a heat oxidation step and an additional step of contacting the closed carbon nanostructure (MWCNT) with a metal to increase oxidation. This alternative method provides additional methods for making highly conducting GNRs which are less than 10 nm in width, using a solution of metal ions. The yield may be more than 80% of GNRs, which may be recovered, e.g., in the supernatant upon high-speed centrifugation.

### Preparation of Graphene Nanoribbons (GNRs)

The present method generally involves obtaining pristine carbon nanotubes (which may be SWNT, MWNT, or several-walled nanotubes, or other closed carbon structures), etching or oxidizing the carbon nanotubes at defect sites, mechanically agitating the etched carbon nanotubes, whereby the etched site extends longitudinally to “unzip,” or longitudinally open the carbon nanotube to form graphene sheets, then centrifuging at high speed and recovering the sheets.

The method uses batch techniques and is suitable for large-scale production of pristine few-layer graphene nanoribbons (GNRs). The unzipping of mildly gas-phase oxidized multiwalled carbon nanotube (MWCNTs) by mechanical sonication in an organic solvent can take place on a large scale. FIG. 1A depicts a schematic of the unzipping process. A multiwalled nanotube which is pristine but having a slight defect is shown at 102. In step 1, the MWNT is subjected to further bond disruption by a heat treatment (calcining). In step 2, the calcined MWNT is agitated in an organic solvent, causing the disrupted area 104 to extend linearly longitudinally and open the top two layers of the MWNT, which has additional inner layers 106 that are not opened. The layers 108, 110 form a GNR having a two-layer graphene thickness. FIG. 1B is a schematic representation of layer 108 of the bi-layer GNR, illustrating the atomically smooth edges as indicated at 112.

### Nanotube Starting Materials

The starting material for the process may be MWCNTs. In one embodiment, pristine MWCNTs synthesized by arc discharge may be used, such as are commercially available, e.g., Buckytubes™ from Aldrich. Aldrich offers several products from the fullerene family, e.g., “Cat. No. 41, 298-8, Bucky tubes, as produced cylinders.” Also available from Aldrich is the semiconjugated copolymer, PmPV (Poly[(m-phenylenevinylene)-co-(2,5-dioctyloxy-p-phenylenevinylene)]; Aldrich Cat. No. 55, 516-9, shown to purify carbon nanotubes by suspending nanotubes, while the accompanying amorphous graphite settles out.

MWCNTs for use in the present methods may also be produced by one of three techniques, namely electric arc discharge, laser ablation and chemical vapor deposition. The arc discharge technique involves the generation of an electric arc between two graphite electrodes, one of which is usually filled with a catalyst metal powder (e.g., iron, nickel, cobalt), in a Helium atmosphere. The laser ablation method uses a laser to evaporate a graphite target which is usually filled with a catalyst metal powder too. The arc discharge and laser ablation techniques tend to produce an ensemble of carbonaceous material which contain nanotubes (30-70%), amorphous carbon and carbon particles (usually closed-caged ones). The nanotubes must then be extracted by some form of purification process before being manipulated into place for specific applications. The chemical vapor deposition process utilizes nanoparticles of metal catalyst to react with a hydrocarbon gas at temperatures of 500-900° C. A variant of this is plasma enhanced chemical vapor deposition in which vertically aligned carbon nanotubes can easily be grown. In these chemical vapor deposition processes, the catalyst decomposes the hydrocarbon gas to produce carbon and hydrogen. The carbon dissolves into the particle and precipitates out from its circumference as the carbon nanotube. Thus, the catalyst acts as a ‘template’ from which the carbon nanotube is formed, and by controlling the catalyst size and reaction time, one can easily tailor the nanotube diameter and length respectively to suit. Carbon tubes, in contrast to a solid carbon filament, will tend to form when the catalyst particle is ˜50 nm or less because if a filament of graphitic sheets were to form, it would contain an enormous percentage of ‘edge’ atoms in the structure. Alternatively, nanotubes may be prepared by catalytic pyrolysis of hydrocarbons as described by Endo, et al., in J. Phys. Chem. Solids, 54, 1841 (1993), or as described by Terrones, et al., in Nature, 388, 52 (1997) or by Kyotani, et al., in Chem. Mater., 8, 2190 (1996), the contents of all of which are incorporated by reference.

### Oxidative Heating Step

The first step in opening the nanotubes into sheets involves expanding defects in the nanotubes by heating the nanotubes to a predetermined temperature that expands the defects without otherwise damaging the nanotubes. MWCNTs are heated in air at high temperatures, preferably around 500° C. Temperatures around 500° C., e.g., 450° C. to 550° C. have been found to be optimum in air, but other temperatures could be used depending on the time of heating and the environment in which the nanotubes are heated; a range of 450-650° C. may be used. The heating step should be sufficient to introduce discrete defect sites into outer wall(s) of the nanotubes or other closed carbon nanostructure, without causing widespread alterations in the sp² bonded network of carbon atoms in the walls. Accordingly, as exemplified, the heating step is a mild condition which removes impurities and etches/oxidizes MWCNTs at defect sites and ends without oxidizing pristine sidewalls of MWCNTs. In this gas-phase oxidation step, oxygen reacts with pre-existing defects on MWCNTs to form etch pits on the sidewalls, a process referred to as “calcining.”

The calcination step leads to gas phase oxidation of pre-existing defects on arc-discharge grown MWCNTs. A low-density structural defect is known to exist on the sidewalls and the ends of high quality arc-derived MWCNTs (Colbert et al, Science 1994, 266: 1218-1222). The defects and ends are more reactive with oxygen than pristine sidewalls during calcination, a condition used for purifying arc-discharge MWCNTs without introducing new defects on sidewalls. Similar to oxidation of defects in the plane of graphite by oxygen (Stevens et al 1998 J. Phys. Chem. B 102: 10799; Lee et al 1999 Phys. Rev. Lett. 82: 217), etch pits are formed at the defects and extend from the outmost sidewall into adjacent inner walls. The depth of pits formed in this step determines the number of layers of the resulting GNRs. Most of the GNRs prepared according to the present methods have been single-, bi- and tri-layers. Material with greater than 3 layers or unreacted material also results. Without wishing to be bound by any scientific theory as to the operation of the present methods, it is thought that formation of etch pits through 2-3 walls on MWCNTs during the calcination step provides initiation points for the unzipping. The oxidation condition is relatively mild without creating new defects in MWCNTs. In the solution-phase sonication process, sonochemistry and hot gas bubbles during sonication cause unzipping, which is initiated at the weak points of etch pits on MWCNTs and proceeds along the tube axis. In a general sense, the present method involves a controlled introduction of defects into one or a few outer walls of a multiwalled closed carbon nanostructure. Defects may be introduced by alternative means, such as high-energy particle bombardment.

### Liquid Agitation Step

After heating, MWCNTs are suspended in an organic liquid dispersant, or solvent, such as 1-2, dichloroethane, ethanol, toluene, methanol, acetone, chloroform, etc. or combinations thereof, which minimizes bundling of the nanotubes. Chlorinated solvents such as chloroform, dichloroethane and dichlorobenzene may be used. Non-chlorinated solvents may also be used. The MWCNTs suspended in organic solvent are agitated, such as by using a method of sonication. It is important during sonication that the solvent or other ingredient provide a source of bubbles. Typically, the organic solvent, as is known, will produce cavitation bubbles (gas bubbles) during sonication.

A polymer may be added to the solvent to act as a surfactant and aid in separation of the nanotubes. Exemplified is (m-phenylenevinylene-co-2,5-dioctoxy-p-phenylenevinylene) (PmPV), but other nanotube coating polymers may be used, such as poly{(5-alkoxy-m-phenylenevinylene)-co-[(2,5-dioctyloxy-p-phenylene)vinylene]} (PAmPV) (further described in US 2007/0117964, entitled “Noncovalent functionalization of nanotubes”) other derivatives of polyphenylenevinylene (PPV), or other conjugated polymers may be used. It is thought that the PmPV coils at a certain angle around a nanotube and helps to separate it from other nanotubes. The nanotubes as suspended in the organic solvent are mechanically agitated. This agitation may be done by a high shear mixer, vortexing, or sonication, e.g., in a high frequency bath or tip sonicator. The agitation is not so severe as to cut (i.e., shorten) or damage the nanotubes, merely to cause extension of the previously formed defects. In the exemplified solution-phase sonication step, sonochemistry and hot gas bubbles enlarge the pits and unzip the tubes. Sonication may be carried out for between 0.5 to less than 2 hours, e.g., around 1.5 hrs. at room temperature in a bath sonicator. During sonication, the calcined MWCNTs are found to unzip into GNRs with high efficiency.

### Recovery of Graphene Sheets

After agitation, the resultant solution is treated to separate the graphene sheets from unopened nanotubes. This may be done by centrifugation at high-speeds, preferably above 30,000 rpm to remove the remaining MWCNTs. The GNRs remain in the supernatant. In one embodiment, ultracentrifugation is carried out at 40,000 rpm for up to 2 hours. In another embodiment, ultracentrifugation results in high yield (>60%) of GNRs in the supernatant. The yield and quantity of high quality GNRs (width 10-30 nm) far exceeds previous sonochemical method of Li et al, Science 319: 1229 (2008) making GNRs easily available for various purposes.

The present method produces a high percentage of GNRs with ultra-smooth edges by simple calcination and sonication steps, which can be performed in many laboratories without highly specialized and expensive equipment. The mechanism of the unzipping differs from previous methods that involved extensive solution-phase oxidation as disclosed in for example Kosynkin et al (Nature 2009, 458: 872-876). The resulting GNRs are separated from the inner tubes and noncovalently functionalized by PmPV via π stacking (Li et al 2008, Science 319: 1229; and Chen et al 2001, J. Am. Chem. Soc. 123: 3838) to afford a homogeneous suspension in the organic solvent.

### Metal-Assisted Oxidation

In an alternate embodiment, metal is used in conjunction with above-referenced heating/oxidation step to further oxidize the nanotube. As exemplified, this involves a second heating step, which follows the first heating step described above. Prior to the second heating step, metal ions in solution are added to the closed carbon nanostructures, (e.g., MWCNTs). As described above, in the first step, the MWCNTs are heated at a high temperature, preferably around 500° C., to purify the nanotube solution of suspended impurities and introduce oxidative defects. In the metal-assisted oxidation method, the nanotubes are then soaked in a solution containing metal ions. The metal ions contact the surface of the MWCNTs and introduce etch pits similar to the reaction of oxygen, as described above. Upon heating at high temperature, with metal-assisted oxidation, the MWCNTs develop multiple defects along more than one position on the circumference of the nanotubes. This facilitates unzipping of the nanotubes along more than one position all along the longitudinal axis to yield GNRs which are very narrow in width. That is, it is thought that there are several strips formed from a single nanotube, so that the width of a ribbon is narrower. The nanotubes subjected to metal ions may be heated again and then dispersed in an organic solution. The nanotubes dispersed in an organic solution are then subjected to agitation, e.g., sonication, as described above. A polymer may be added to this sonication process as described above. GNRs with widths of between 2-15 nm are obtained with the metal-assisted oxidation process. Centrifugation at high-speed or ultra-centrifugation leads to a yield of 80% GNRs in the supernatant.

A wide variety of metals may be used in this process, provided that they are oxidized and can contact the closed carbon nanostructure. Metals used in the process may be, for example, Cu, Na, Au, Ag, Pt, Ir, Pd, Ni. Metal ions may be added by use of metal ion salts such as chloride, sulphate, nitrate, acetate, chlorate, permanganate, etc. Copper (II) worked particularly well, and may form a variety of salts, as described above, for ease of handling (in liquid) in the process.

Devices can be formed with the narrow (<10 nm) GNRs. A GNR of about 3 nm has been shown to have an Iₒₙ/I_{off} ratio of greater than 10⁶, at room temperature, showing the ability of a GNR as presently made to act in a semiconductor device with controllable on-state current versus off-state current. Further details on testing methods of GNR devices may be found in Zhang et al., “Graphene nanoribbon Tunnel Transistors,” IEE Electron Device Lett. 29(12) 1344-1346 (2008).

### Characterization of GNRs

In one aspect of the invention, it was found that unique GNRs were formed by the present methods. Atomic force microscopy (AFM) is used to characterize the MWCNTs and GNRs. The materials are deposited on substrates commonly used in AFM. An example of a substrate is SiO₂/Si. AFM may be carried out on a standard instrument such as Nanoscope Ma multimode instrument. Tapping mode-AFM may be used. In another aspect, high yield GNRs are characterized using transmission electron microscopy (TEM). TEM may be carried out using for example FEI Tecnai F20 X-TWIN transmission electron microscope. In another aspect, GNRs are characterized using Raman spectroscopy. The Raman I_{D}/I_{G} ratio is widely used to evaluate the quality of carbon nanotubes (Dresselhaus et al 2005, Phys. Rep. 409:47) and graphene materials (Ni et al 2008, Nano Res. 1:273).

The majority of GNRs obtained by the present method are distinguished as bi-layered or tri-layered with a width range of 10-30 nm. In one aspect, GNRs uniform in width with very little edge roughness are obtained in the present invention. In another aspect, the Raman I_{D}/I_{G} ratio of the GNRs is lower than 0.5, or lower than 0.3, and in some cases lower than 0.2. A low ratio points to overall low defect density and to a very high quality of the product.

As is known, Raman spectroscopy is a light scattering technique, and can be thought of in its simplest form as a process where a photon of light interacts with a sample to produce scattered radiation of different wavelengths. Changes in a nanostructure are observable by the separation of the Raman G (tangential mode) and D (disorder induced) peaks, a lower R-value (I_{D}/I_{G} ratio), and an increase in the intensity of the second order peaks. A more detail description of obtaining I_{D}/I_{G} ratios is found, for example, in Sethi, R.; Barron, A. Characterization of Single-Walled Carbon Nanotubes by Raman Spectroscopy, Connexions Web site. http (colon slash slash)cnx.org/content/m22925/1.2/May 23, 2009.

### GNR Electrical Devices

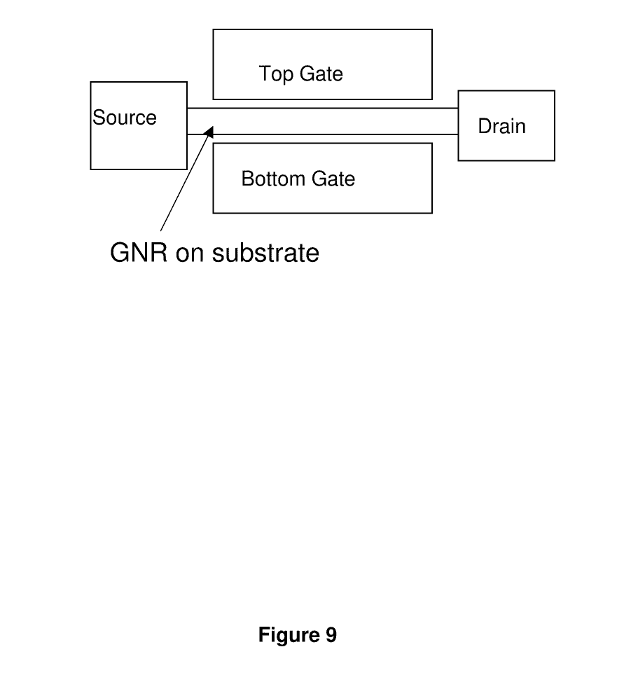

The high yield of GNRs suspended in an organic solution greatly simplified fabrication of GNR electrical devices. The simplest GNR electrical device simply comprises connecting ends of the GNR to two electrodes. A GNR FET may be fabricated, e.g., as shown in FIG. 9.

FIG. 9 is diagram showing a GNR laying on a substrate and connected at lengthwise end portions to electrodes, indicated as source and drain electrodes. A top gate and bottom gate also interact with the NR, as in a typical FET. The schematic is for illustrative purposes. All FETs have a gate, drain, and source terminal that correspond roughly to the base, collector, and emitter of junction transistors. FETs also have a fourth terminal called the body, base, bulk, or substrate.

Field effect transistors (FET)-like GNR devices are fabricated by making large array of source (S) and drain (D) electrodes to contact randomly deposited GNRs on SiO₂ (300 nm)/p++−Si substrates. The array of electrodes may be fabricated using electron beam lithography followed by electron-beam evaporation of palladium. The p++−Si is used as back gate and Pd (30 nm) is used as S and D electrodes. Electrical annealing in vacuum is used as disclosed in Wang et al 2009, Science 324: 768 and in Jiao et al 2009, Nature 458: 877 to remove adsorbates from the GNRs by applying a bias voltage of ˜2 V.

In one embodiment, GNRs of the present invention exhibit a very high conductance of up to 5 e²/h. In another embodiment, at temperatures around 4.2° K, the conductance of the GNR device is at least one order of magnitude higher than similar previous devices. In another embodiment, the GNRs of the present invention show lowest resistivity as compared to similar GNRs to date. In one example, the resistivity is less than 2 kΩm, preferably less than 1.8 kΩm. In another example, the resistivity is 1.6 kΩm. In another embodiment, the GNRs showed phase coherent transport as demonstrated by interference pattern at differential conductance.

### EXAMPLES

### Example 1

### Preparation of GNRs

30 mg MWCNTs (Aldrich, 406074-500MG) were calcined at 500° C. in a 1-inch tube furnace for 2 hrs. After that, 15 mg calcined MWCNTs and 7.5 mg poly (m-phenylenevinylene-co-2,5-dioctoxy-p-phenylenevinylene) (PmPV, Aldrich, 555169-1G) were dissolved in 10 mL 1,2-dichloroethane (DCE) and then sonicated for 1 hr. After that, the solution was ultracentrifuged at 40,000 rpm for 2 hrs. The supernatant was collected for characterization and found to contain ˜60% GNRs.

### Example 2

### Optimization of the Unzipping Process

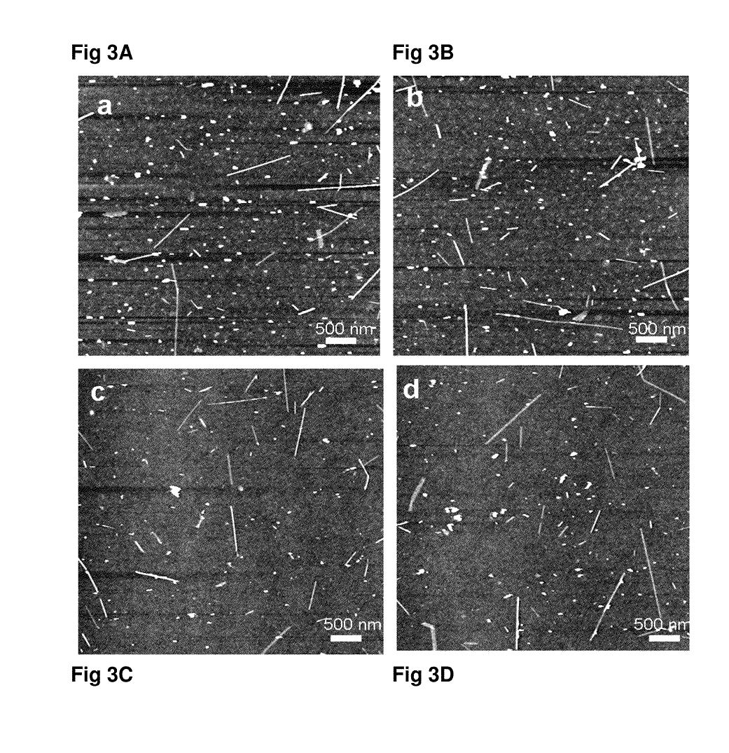

The present method of GNR formation was a simple two-step process and both steps were critical. The pits introduced by calcination made it possible to unzip the MWCNTs by mechanical breaking in the sonication step. The temperature of calcination was related to the activation energies for pits growth and therefore, determined the yield and quality of the obtained GNRs. It was found that 500° C. was the optimized temperature for the production of GNRs at a good yield. Next, the sonication conditions were tested. The calcined MWCNTs were sonicated in DCE for different durations, the solution was briefly centrifuged at low speed (15,000 rpm) to remove the aggregates without losing many GNRs and then deposited onto SiO₂/Si substrates. The percentages of GNRs were <10%, ˜30% and ˜40% after sonication for 0.5, 1, and 2 hrs, respectively. The GNRs obtained upon sonicating for different times were studied by AFM. The obvious dependence of the percentage of GNRs on sonication time indicated that sonication played an important role in the unzipping process. Even longer sonication degraded the quality of GNRs as evidenced by the increase of resistivity after sonicating for 2 hrs. Other solvents and surfactants for use during sonication were tried, such as chloroform, DMF and NMP; it was found that that DCE and PmPV were the best combination for the production of GNRs. To obtain higher percentage of GNRs, ultracentrifuge was used to further separate MWCNTs from GNRs. The percentage of GNRs made by sonicating for 1 hr increased to ˜60% after centrifuging at 40,000 rpm for 2 hrs (FIG. 3). Thus, it was concluded that the optimized steps for the production of GNRs with both high yield and quality of GNRs comprised: First, MWCNTs were calcined in air at 500° C. for 2 hrs. After that, the calcined MWCNTs were sonicated for 1 hr in PmPV/DCE solution and then ultracentrifuged at 40,000 rpm for 2 hrs.

### Example 3

### Characterization of GNRs

AFM images of GNRs were obtained with a Nanoscope Ma multimode instrument in tapping mode. The samples for AFM imaging were prepared by soaking the SiO₂/Si substrates in the GNRs suspension for 15 min, rinsing with isopropanol and then blowing dried. Before AFM imaging, the substrates were calcined at 350° C. for 20 min to remove PmPV.

GNRs were characterized using a FEI Tecnai G2 F20 X-TWIN transmission electron microscope (TEM) at an accelerating voltage of 120 kV or 200 kV. The TEM samples were prepared by soaking porous Si grids (SPI Supplies, US200-P15Q UltraSM 15 nm Porous TEM Windows) in a GNRs suspension overnight and then calcined at 400° C. for 20 min.

For characterization of individual GNRs by Raman spectroscopy, low density GNRs were obtained on SiO₂/Si substrates with makers by soaking the substrates in GNRs suspensions for 2 min. Then individual GNRs were located with markers by AFM. Raman spectra of individual GNRs were collected with Horiba Jobin Yvon LabRAM HR Raman microscope with a 633 nm He—Ne laser excitation (spot size ˜1 μm, power ˜10 mW). The step size of mapping was 100 nm and the integration time was 5 s at each spot.

### Example 4

### Characterization of GNR Quality by Microscopy

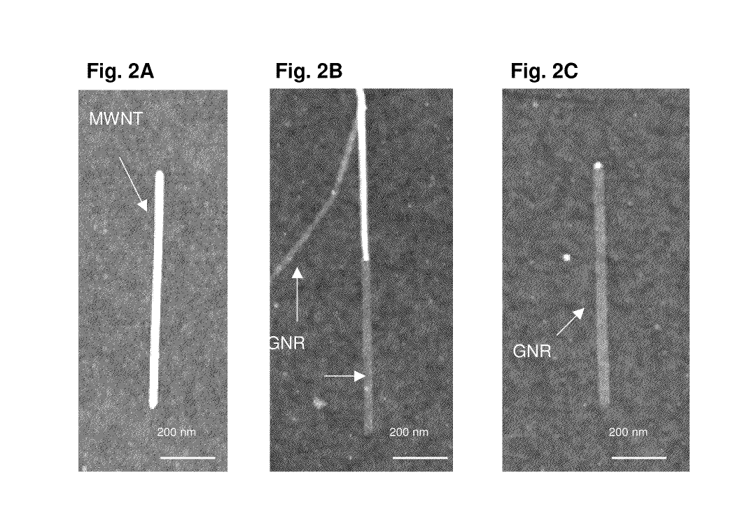

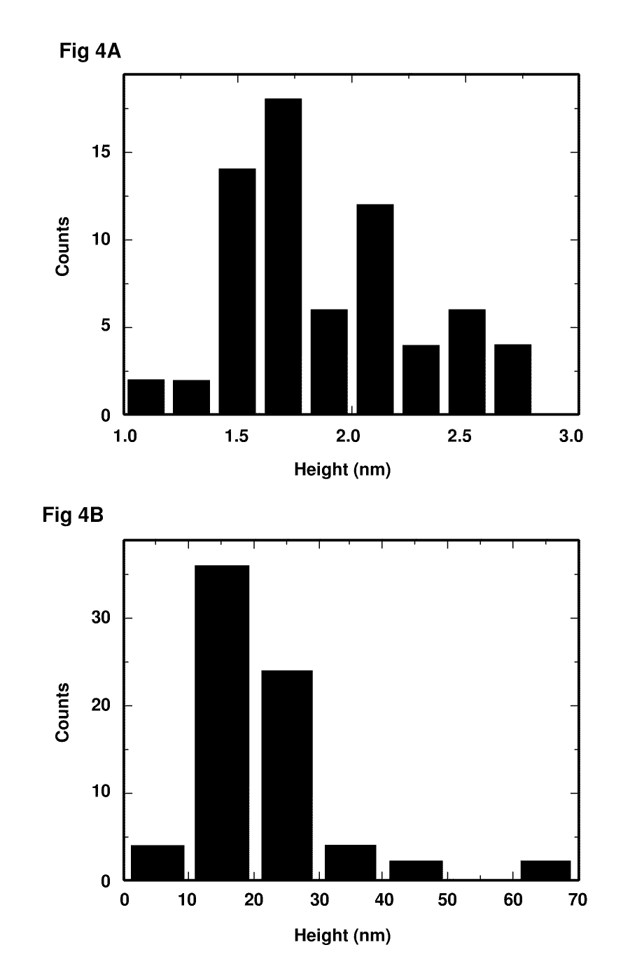

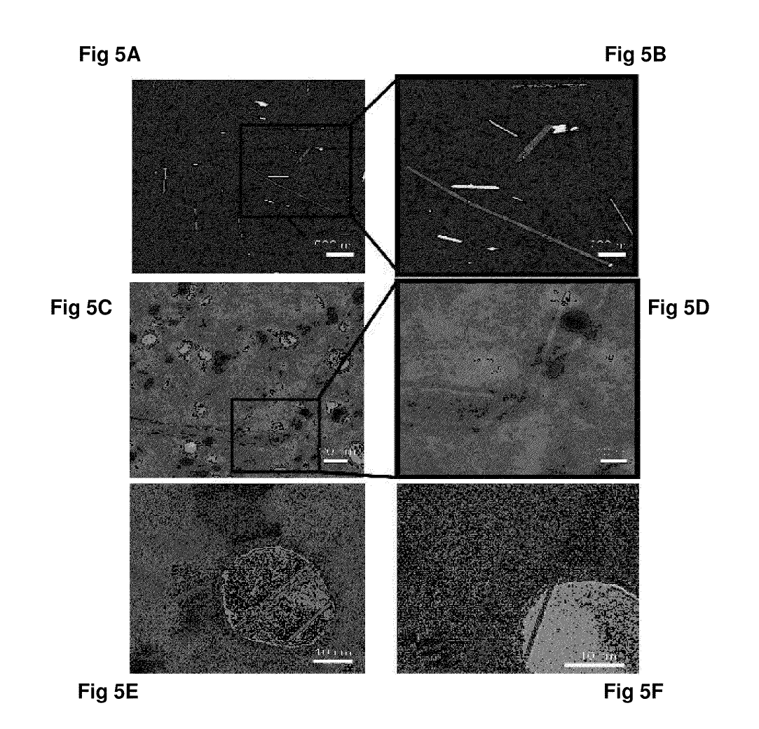

Atomic force microscope (AFM) was used to characterize MWCNTs and the unzipped products deposited on SiO₂/Si substrates. GNRs were easily distinguished from MWCNTs due to obvious decreases in apparent heights (1-2 nm in height for GNRs, FIG. 2 A to C, FIG. 4). The average diameter (height) of the starting MWCNTs was ˜8 nm. About 60% of the products were bi- and tri-layers GNRs with widths in 10-30 nm range (FIGS. 5A and B, FIG. 4). Under AFM, the GNRs appeared very uniform in width with little edge roughness along their lengths (FIG. 5B). In additional studies, AFM images of unzipped MWCNTs deposited on SiO₂/Si substrate revealed GNRs with 10 nm and 16 nm widths. Heights of 1.4 nm or 1.5 nm were also observed for GNRs by AFM. The high yield of GNRs enabled easy characterization of GNRs by transmission electron microscopy (TEM). A ˜12 nm wide GNR with a fold along its length was observed by TEM (FIG. 5C). The kink structure (FIG. 5D) illustrated excellent flexibility of GNRs compared to rigid MWCNTs. High resolution TEM of GNRs revealed straight and nearly atomically smooth edges without any discernable edge roughness (FIGS. 5E and F). TEM images also showed GNRs with different widths, for example in some TEM images, GNRs with 15 nm widths were observed, in other TEM images, GNRs with 17 nm width were observed. This is the first time atomically smooth edges of narrow (<20 nm) GNRs is observed in TEM. The parallel lines at the edges of our GNRs (inter-line spacing of 3.7-4 Å) could be due to the bi- or tri-layer nature of our GNRs and the successively smaller widths of each layer due to the decreasing circumference of inner MWCNT shells.

### Example 5

### Characterization of GNR Quality by Raman Spectroscopy

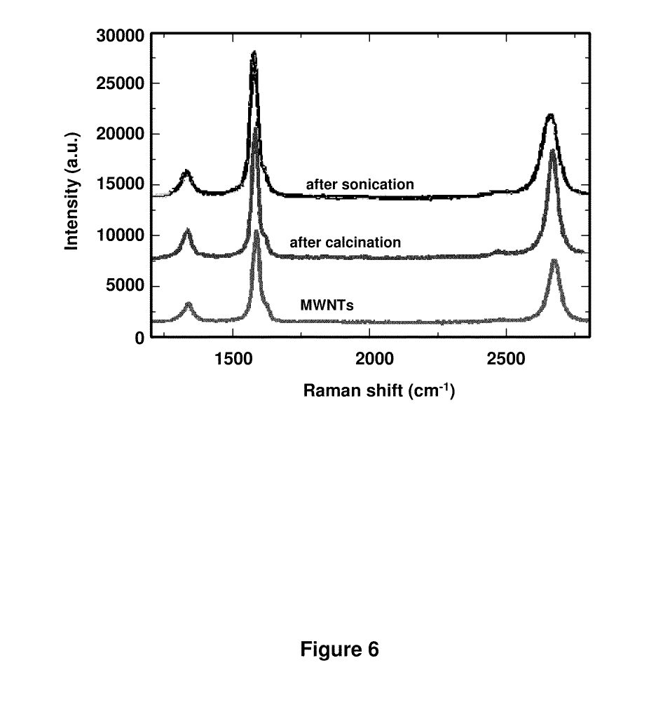

Raman data of pristine, calcined MWCNTs and unzipped products in bulk was collected. The samples were made by drop-drying the pristine, calcined and unzipped MWCNTs dispersed in DCE onto SiO₂/Si substrates to form thick films. All the spectra were taken with a 633 nm He—Ne laser excitation at ˜1 mW for 10 s. The I_{D}/I_{G} ratios of these three samples were 0.20, 022 and 0.16, respectively (FIG. 6). After the gas phase calcination step, the I_{D}/I_{G} of MWCNTs did not increase, which indicated the oxidation was very mild and did not introduce new defects. The I_{D}/I_{G} of the unzipped products was much lower than those of bulk GNRs (ID/IG>1) made by previous workers by unzipping in solution (as disclosed in Li et al 2008, Science 319: 1229 and Wang et al 2008, Phys. Rev. Lett. 100: 206803) and CVD growth (as disclosed in Wang et al 2009, Science 324: 768 and Chen et al 2007, Physica. E 40: 228), indicated higher quality of GNRs made by the present method. The ensemble-averaged I_{D}/I_{G} ratio of the final bulk product containing ˜60% GNRs was only ˜0.2 (FIG. 6), similar to that of the starting pristine MWCNTs and suggested overall low defect density in the product.

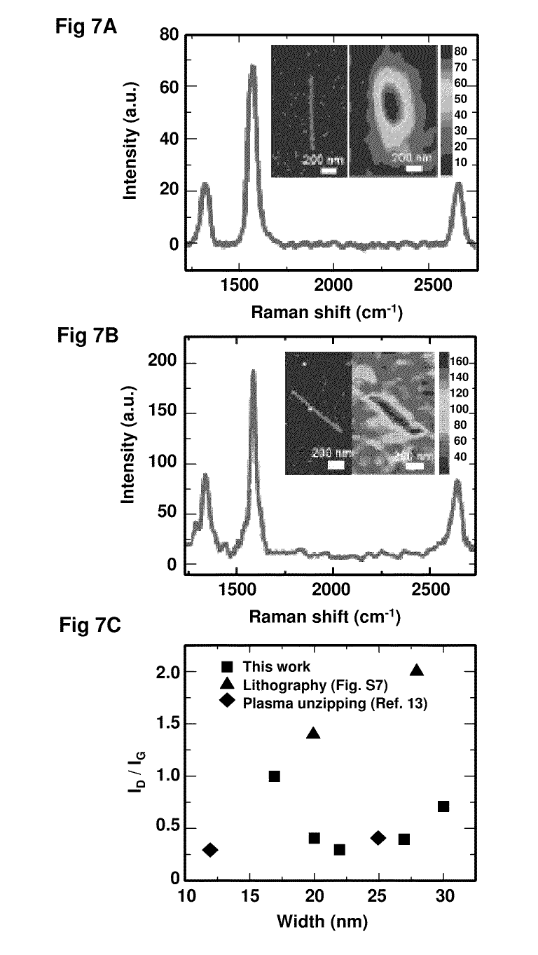

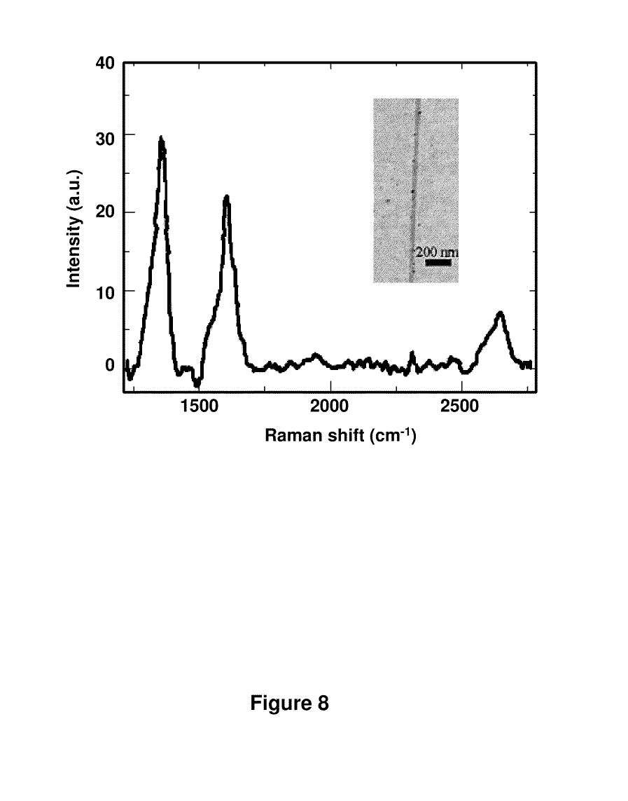

Conformal Raman mapping of individual bi- and tri-layer GNRs deposited on SiO₂/Si substrates was also carried out (FIGS. 7A and B). The averaged I_{D}/I_{G} ratio of bi-layer GNRs with 10-30 nm widths was ˜0.5 (FIG. 7C), much lower than lithographic patterned GNRs (I_{D}/I_{G>1}, FIG. 8) and wide GNRs unzipped by solution-phase oxidation (I_{D}/I_{G}>1) as disclosed in Kosynkin et al 2009, Nature 458: 872 and Zhang et al 2009, J. Am. Chem. Soc. 131: 13460. I_{D}/I_{G} ratios were used to compare the quality of our GNRs with GNRs made by various methods. Except for a few publications (Li et al 2008 Science 319: 1229; Jiao et al 2009, Nature 458: 877), there were no reported Raman data of individual bilayer GNRs with widths of 10-30 nm. The I_{D}/I_{G} ratios of individual bilayer GNRs made by different methods were compared. FIG. 8 shows the Raman spectrum of a typical 20-nm-wide bilayer GNR made by lithographic patterning with an I_{D}/I_{G} of ˜1.3. Besides lithographic patterning, bilayer GNRs can also be produced by plasma unzipping MWCNTs (as described in Jiao et al 2009, Nature 458: 877). The average I_{D}/I_{G} of bilayer GNRs made by plasma unzipping was ˜0.5.

### Example 6

### Fabrication of GNR Devices

Electron-beam lithography followed by electron-beam evaporation of palladium (30 nm) was used to fabricate a large array of 98 source and drain electrodes on 300-nm SiO₂/p++Si substrates with pre-deposited GNRs. The channel length of these devices was ˜250 nm and the width of source and drain electrodes was ˜5 μm. The devices were then annealed in Ar at 220° C. for 15 min to improve the contact quality. AFM was then used to identify devices with a single GNR connection. The yield of such devices on a chip is ˜10-15%.

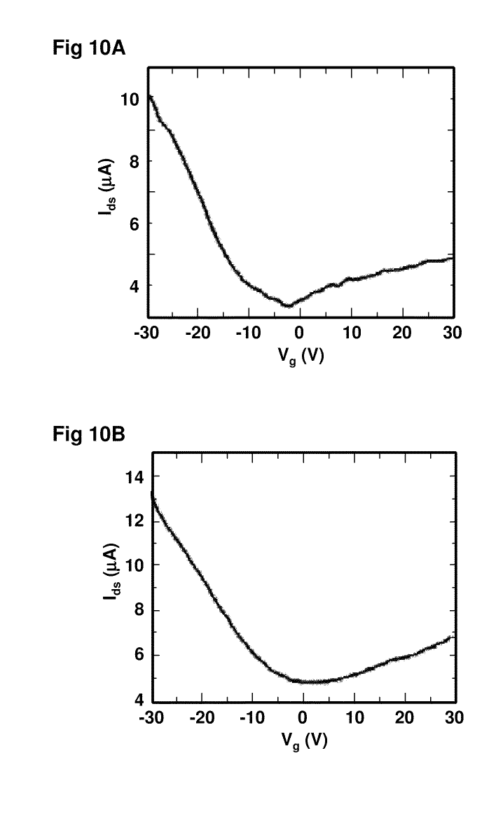

The high yield of GNRs suspended in an organic solution greatly simplified fabrication of GNR electrical devices. FET-like GNR devices were fabricated by simply making large array of source (S) and drain (D) electrodes to contact randomly deposited GNRs on SiO₂ (300 nm)/p++−Si substrates and obtained ˜15% single GNR devices. The p++−Si was used as back gate and Pd (30 nm) was used as S and D electrodes. Electrical annealing in vacuum was used to remove adsorbates from the GNRs by applying a bias voltage of ˜2 V. The current-gate voltage (I_{ds}-V_{gs}) curves of most bi- and tri-layer GNRs devices showed clear Dirac points at ˜0 V after electrical annealing. (FIG. 10). Individual GNRs exhibited 0.5-5e²/h conductance at room temperature. For example, G-V_{gs} curves of a 14-nm-wide bi-layer GNR at 20 K, 100K and at 290 K at Vds=1 mV were obtained. The lowest resistivity (defined as R×W/L, where R is the resistance of the device, and W and L indicate GNR width and channel length, respectively) at the Dirac point observed in present band tri-layer GNRs with 10-30 nm widths was ˜1.8 and 1.6 kΩm, respectively. This was the lowest resistivity of GNRs ever reported for GNRs with similar layer numbers (as reported by Li et al 2008, Science 319: 1229; Jiao et al 2009, Nature 458: 877; Kosynkin et al, Nature 458: 872; and Lin & Avouris 2008, Nano Lett. 8: 2119), confirming the high quality of GNRs produced by the present method.

### Example 7

### Electrical Transport in GNRs

Variable temperature electrical transport in GNRs showed that conductance of the p-channel of a bi-layer GNR (W ˜14 nm, L ˜200 nm) increased as the device was cooled from 290 K to 50 K (further cooling introduced some oscillations in the G-V_{gs} characteristics). This suggested metallic behavior for transport in the valence band of the narrow GNR with reduced acoustic phonon scattering at lower temperatures. Carrier scattering in present high quality, smooth-edged GNRs was not dominant by defects, charged impurities or edge roughness, as in the case of GNRs obtained by lithographic patterning, which showed increased resistance at lower temperature due to localization effects by defects (as disclosed in Han et al 2007, Phys. Rev. Lett. 98: 206805 and Han et al 2009, arXiv:0910.4808v1). At 4.2° K, the conductance of present device G ˜3-4-e2/h is at least one order of magnitude higher than similar previous GNR devices. Conductance oscillations versus V_{gs} were observed at 4.2° K, and differential conductance dI_{ds}/dV_{ds} versus V_{gs} and V_{ds} exhibited interference pattern with peak conductance ˜4e2/h. This was similar to Fabry-Perot interference previously observed in pristine carbon nanotubes (Liang et al 2001, Nature 411: 665), suggesting phase coherent transport and interference of several modes or subbands of electrons in the GNR. Similar interference pattern was only observed in a much wider and shorter graphene sample (Todd et al 2009, Nano Lett. 9: 416). It is remarkable that electron waves travel ˜200 nm in an open-edged narrow GNR (W ˜14 nm) without loss of phase coherence. The high conductance and phase coherent transport in the valance band of present GNRs again confirmed the high quality of GNRs made by presently disclosed new approach and transparent contacts between the valance band of GNRs and Pd. On the other hand, the conductance of the n-channel of GNRs gradually decreased at lower temperature, indicating a barrier for transport through the conduction band. This barrier is likely due to a small Schottky barrier between Pd and the conduction band of the W ˜14 nm GNR. Band gap of the GNR was estimated to be Eg˜10-15 meV by fitting the temperature dependence of minimum conductance to thermal activation over a barrier of ˜Eg/2.

### Example 8

### Room Temperature Transport Measurement of Bi- and Tri-Layer GNRs and the Comparison of Resistivity of Bilayer GNRs Made by Different Methods

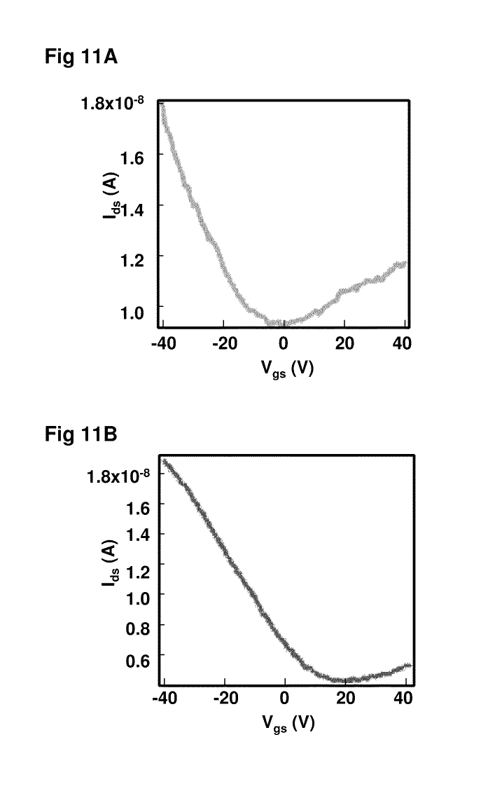

FIG. 10 shows the typical I_{ds}-V_{gs} curves of bi- and trilayer GNRs at room temperature in vacuum after the electrical annealing. Most of the obtained GNR devices showed clear Dirac points at around 0 V after electrical annealing. The room temperature resistivity of bilayer GNRs with 10-30 nm widths made by different methods, including lithographic patterning (Lin & Avouris 2008, Nano Lett. 8: 2119), sonochemical (Li et al 2008, Science 319: 1229) method and plasma unzipping was compared (Jiao et al 2009, Nature 458: 877) and it was found that resistivity of GNRs obtained by the present method was the lowest at all widths between 10 and 50 nm. FIG. 11 shows the typical I_{ds}-V_{gs} curves of bilayer GNRs made by lithographic patterning which shows much higher resistivity than the present invention.

### Example 9

### Production of Sub-10 nm GNRs by Metal-Assisted Oxidation; and Fabrication of a GNR Device

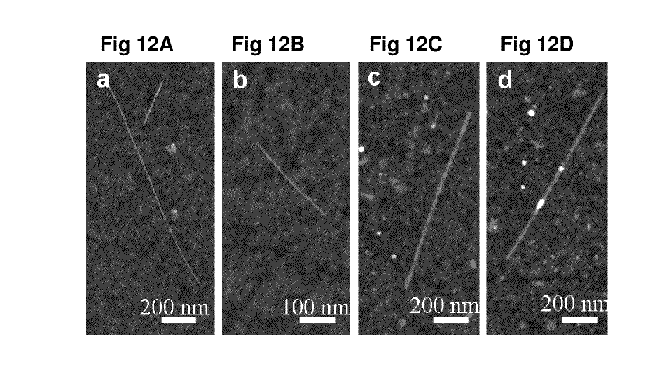

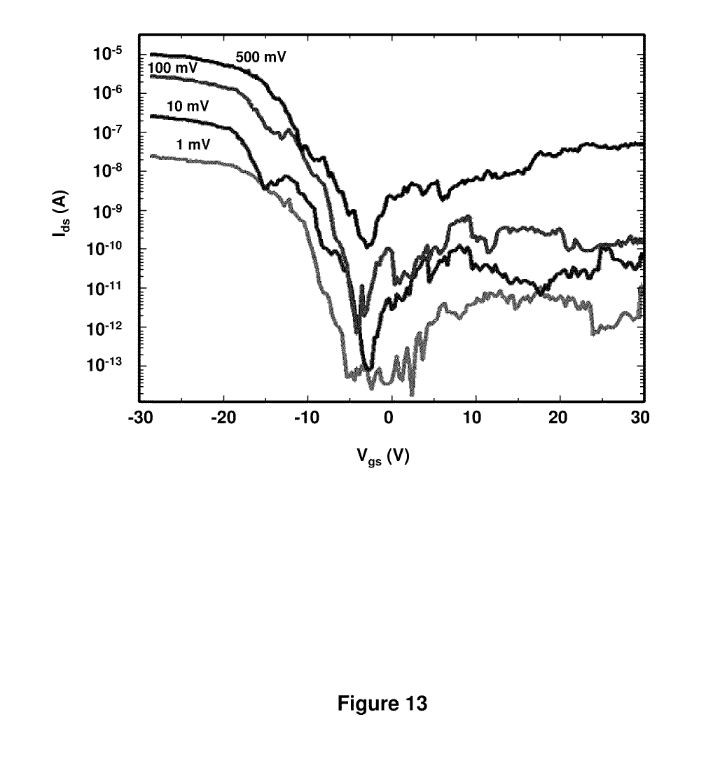

30 mg MWCNTS were calcined at 500° C. in a 1-inch tube furnace for 2 hours. The calcined MWCNTs were then soaked in 10 mM Cu (NO₃)₂ solution in methanol for 30 min. After removing the extra Cu (NO₃)₂ by a brief centrifugation, the obtained MWCNTs with Cu (which is thought to decorate the outer walls) were calcined again at 500° C. for 30 min. The second calcining step may be carried out at a lower temperature than the first. The MWCNTs were dispersed in 1,2-dichloroethane with poly (m-phenylenevinylene-co-2,5-dioctoxy-p-phenylenevinylene) (PmPV) and sonicated for 1.5 hours. Finally, the solution was centrifuged at 40,000 rpm for 2 hours. The supernatant was found to contain 80% GNRs. AFM images of the obtained GNRs showed a width distribution of between 2-15 nm. FIG. 12 shows AFM images of examples of sub-10 nm GNRs obtained by metal (Cu)-assisted oxidation during the calcination. Sub-10-nm GNRS were also obtained when sodium (Na) or gold (Au) salts were used, however the yield and quality were lower than that obtained with Cu. Sub-10-nm GNR devices showed very low resistivity at room temperature. FIG. 13 shows the transfer characteristics (current vs. gate voltage I_{ds}-V_{gs}) under various V_{ds} for a 3-nm-wide GNR device. Iₒₙ/I_{off} ratio of more than 10⁶ is seen at room temperature.

A 3 nm wide GNR as in the present device will have semiconductor properties, whereas wider GNRs are more metallic. The transfer characteristics exemplified here show the desirable IV characteristics of narrow GNRs (less than 10 nm wide) at different V_{ds} (drain-source voltages).

### CONCLUSION

The above specific description is meant to exemplify and illustrate the invention and should not be seen as limiting the scope of the invention, which is defined by the literal and equivalent scope of the appended claims. Any patents or publications mentioned in this specification, including the references cited below are indicative of levels of those skilled in the art to which that patent or publication pertains as of its date and are intended to convey details of the invention which may not be explicitly set out but which would be understood by workers in the field. Such patents or publications are hereby incorporated by reference to the same extent as if each was specifically and individually incorporated by reference, as needed for the purpose of describing and enabling the method or material referred to.

### REFERENCES

1. Li, X. L. et al. Chemically derived, ultrasmooth graphene nanoribbon semiconductors. Science 319, 1229-1232 (2008).
2. Wang, X. R. et al. Room-temperature all-semiconducting sub-10-nm graphene nanoribbon field-effect transistors. Phys. Rev. Lett. 100, 206803 (2008).
3. Wang, X. R. et al. N-doping of graphene through electrothermal reactions with ammonia. Science 324, 768-771 (2009).
4. Chen, Z. H., Lin, Y. M., Rooks, M. J.& Avouris, P. Graphene nano-ribbon electronics. Physica. E 40, 228-232 (2007).
5. Han, M. Y., Ozyilmaz, B., Zhang, Y. B.&Kim, P. Energy band-gap engineering of graphene nanoribbons. Phys. Rev. Lett. 98, 206805 (2007).
6. Tapaszto, L., Dobrik, G., Lambin, P.& Biro, L. P. Tailoring the atomic structure of graphene nanoribbons by scanning tunnelling microscope lithography. Nat. Nanotechnol. 3, 397-401 (2008).
7. Bai, J. W., Duan, X. F. & Huang, Y. Rational fabrication of graphene nanoribbons using a nanowire etch mask. Nano Lett. 9, 2083-2087 (2009).
8. Datta, S. S., Strachan, D. R., Khamis, S. M. &Johnson, A. T. C. Crystallographic etching of few-layer graphene. Nano Lett. 8, 1912-1915 (2008).
9. Ci, L. J., Xu, Z. P., Wang, L. L., Gao, W., Ding, F., Kelly, K. F., Yakobson, B. I. & Ajayan, P. M. Controlled nanocutting of graphene. Nano Res. 1, 116-122 (2008).
10. Campos, L. C., Manfrinato, V. R., Sanchez-Yamagishi, J. D., Kong, J. & Jarillo-Herrero, P. Anisotropic Etching and nanoribbon formation in single-layer graphene. Nano Lett. 9, 2600-2604 (2009).
11. Campos-Delgado, J. et al. Bulk production of a new form of sp2 carbon: Crystalline graphene nanoribbons. Nano Lett. 8, 2773-2778 (2008).
12. Wei, D. C. et al. Scalable synthesis of few-layer graphene ribbons with controlled morphologies by a template method and their applications in nanoelectromechanical switches. J. Am. Chem. Soc. 131, 11147-11154 (2009).
13. Jiao, L. Y., Zhang, L., Wang, X. R., Diankov, G. & Dai, H. J. Narrow graphene nanoribbons from carbon nanotubes. Nature 458, 877-880 (2009).
14. Kosynkin, D. V. et al. Longitudinal unzipping of carbon nanotubes to form graphene nanoribbons. Nature 458, 872-876 (2009).
15. Zhang, Z. X., Sun, Z. Z., Yao, J., Kosynkin, D. V. & Tour, J. M. Transforming carbon nanotube devices into nanoribbon devices. J. Am. Chem. Soc. 131, 13460-13463 (2009).
16. Cano-Marquez, A. G. et al. Ex-MWNTs: Graphene sheets and ribbons produced by lithium intercalation and exfoliation of carbon nanotubes. Nano Lett. 9, 1527-1533 (2009).
17. El as, A. L., et al. Longitudinal cutting of pure and doped carbon nanotubes to form graphitic nanoribbons using metal clusters as nanoscalpels. Nano Lett. ASAP DOI: 10.1021/n1901631z (2009).
18. Kim, W. S. et al. Fabrication of graphene layers from multiwalled carbon nanotubes using high dc pulse. Appl. Phys. Lett. 95, 083103 (2009).
19. Colbert, D. T. et al. Growth and sintering of fullerene nanotubes. Science 266 (5188), 1218-1222 (1994).
20. Barinov, A., Gregoratti, L., Dudin, P., La Rosa, S. & Kiskinova, M. Imaging and Spectroscopy of multiwalled carbon nanotubes during oxidation: defects and oxygen bonding. Adv. Mater. 21, 1916-1920 (2009).
21. Stevens, F., Kolodny, L. A. & Beebe, T. P. Kinetics of graphite oxidation: Monolayer and multilayer etch pits in HOPG studied by STM. J. Phys. Chem. B 102, 10799-10804 (1998).
22. Lee, S. M. et al. Defected-induced oxidation of graphite. Phys. Rev. Lett. 82, 217 (1999).
23. Chen, R. J., Zhang, Y. G., Wang, D. W., & Dai, H. J., Noncovalent sidewall functionalization of single-walled carbon nanotubes for protein immobilization. J. Am. Chem. Soc. 123, 3838-3839 (2001).
24. Dresselhaus, M. S., Dresselhaus, G., Saito, R. & Jorio, A. Raman spectroscopy of carbon nanotubes. Phys. Rep. 409, 47-99 (2005).
25. Ni, Z. H., Wang, Y. Y., Yu, T. & Shen, Z. X. Raman spectroscopy and imaging of graphene. Nano Res. 1, 273-291 (2008).
26. Lin, Y. M.& Avouris, P. Strong suppression of electrical noise in bilayer graphene nanodevices. Nano Lett. 8, 2119-2125 (2008).
27. Han, M. Y., Brant, J. C., & Kim, P. Electron transport in disordered graphene nanoribbons. arXiv:0910.4808v1 (2009).
28. Liang, W. et al. Fabry-Perot interference in a nanotube electron waveguide. Nature 411, 665-669 (2001).
29. Todd, K., Chou, H. T., Amasha, S., & Goldhaber-Gordon, D. Quantum dot behavior in graphene nanoconstrictions. Nano Lett 9, 416-421 (2009).

What is claimed is:

1. A method for production of graphene nanoribbons comprising the steps of:
(a) heating closed carbon nanostructures at a temperature, between 400° C. and 700° C., sufficient to induce oxidation but not thermal decomposition of the closed carbon nanostructures and produce partially etched closed carbon nanostructures;
(b) dispersing said partially etched closed carbon nanostructures in an organic solvent;
(c) mechanically agitating said partially etched closed carbon nanostructures in said organic solvent under conditions whereby said partially etched closed carbon nanostructures open to form graphene nanoribbons; and
(d) recovering said graphene nanoribbons from said organic solvent.

2. The method of claim 1 wherein said recovering comprises centrifugation, and said graphene ribbons are in a supernatant.

3. The method of claim 2 wherein said graphene nanoribbons comprise more than 60% of solid carbon compounds in said supernatant.

4. The method of claim 1 wherein said heating takes place between 450° C. and 550° C.

5. The method of claim 1 wherein said organic solvent is 1,2-dichloroethane.

6. The method of claim 1 further comprising the step of adding to said partially etched carbon nanostructures in an organic solvent a polymer for contacting and separating the nanostructures.

7. The method of claim 6 wherein said polymer is poly (m-phenylenevinylene-co-2,5-dioctoxy-p-phenylenevinylene).

8. The method of claim 1 wherein said graphene nanoribbons have a width between about 2 nm and 30 nm.

9. The method of claim 1 wherein said graphene nanoribbons have atomically smooth edges.

10. The method of claim 1 wherein the multiwalled carbon nanostructures are multiwalled carbon nanotubes.

11. The method of claim 1 wherein single-, bi- and tri layer graphene nanoribbons together comprise more than 50% of said graphene nanoribbons.

12. The method of claim 1 further comprising the step of applying recovered graphene nanoribbons to electrodes to form a GNR device.

13. The method of claim 12 wherein the electrodes are part of an FET device.

14. The method of claim 12 wherein said GNR device has an electrical conductance of up to 5 e2/h.

15. The method of claim 12 wherein the resistivity of said GNR device is less than 2 kΩ.

16. The method of claim 12 wherein the resistivity of said GNR device is less than 1.8 kΩ.

17. The method of claim 12 wherein said GNR device exhibits phase coherent transport at low temperature.

18. The method of claim 1 further comprising the step of heating said partially etched closed carbon nanostructures in the presence of a metal.

19. The method of claim 18 wherein said metal is copper.

20. The method of claim 18 wherein said graphene nanoribbons are less than about 10 nm wide.

21. A graphene nanoribbon having a discrete number of layers, between one and four, a width between about 10 and 30 nm and having surface integrity sufficient to yield a Raman Peak ratio of ID/IG less than about 0.5.

22. A graphene nanoribbon for use in a field effect transistor, having a discrete number of layers, between one and four, a width less than about 10 nm, and an Iₒₙ/I_{off} ratio of at least about 10⁶.
